(19) United States
(12) Patent Application Publication
(10) Pub. No.: US 2019/0220151 A1
(43) Pub. Date: Jul. 18, 2019

(54) LAMINATE FOR TOUCH PANEL, FLEXIBLE DEVICE, AND ORGANIC ELECTROLUMINESCENCE DISPLAY DEVICE

(71) Applicant: FUJIFILM Corporation, Tokyo (JP)

(72) Inventor: Tetsuro MITSUI, Kanagawa (JP)

(73) Assignee: FUJIFILM Corporation, Tokyo (JP)

(21) Appl. No.: 16/368,112

(22) Filed: Mar. 28, 2019

Related U.S. Application Data
(63) Continuation of application No. PCT/JP2017/036678, filed on Oct. 10, 2017.

(30) Foreign Application Priority Data
Oct. 31, 2016 (JP) 2016-213751

(51) Int. Cl. G06F 3/044; H01L 27/32

(52) U.S. Cl. CPC G06F 3/0445; G06F 2203/04112; G06F 2203/04102; H01L 27/323

(57) ABSTRACT

A flexible device and an organic electroluminescence display device that include a laminate for a touch panel. The laminate for a touch panel that is bendable, comprising a plurality of members and is bendable, in which at least one of the members is a member including a conductive portion, at least one of the members is an adhesive film, and the adhesive film has a 180 degree peel strength of 0.5 N/mm or higher with respect to an adjacent member and has a thickness of 30 μm or more.

### CROSS-REFERENCE TO RELATED APPLICATIONS

This application is a Continuation of PCT International Application No. PCT/JP2017/036678, filed on Oct. 10, 2017, which claims priority under 35 U.S.C. § 119(a) to Japanese Patent Application No. 2016-213751, filed on Oct. 31, 2016. Each of the above application(s) is hereby expressly incorporated by reference, in its entirety, into the present application.

### BACKGROUND OF THE INVENTION

### 1. Field of the Invention

The present invention relates to a laminate for a touch panel, a flexible device, and an organic electroluminescence display device.

### 2. Description of the Related Art

Recently, an installation rate of a touch panel into a mobile phone, a portable game machine, or the like has increased. For example, a capacitive touch panel (hereinafter, also simply referred to as “touch panel”) capable of multi-point detection has attracted attention.

In general, as disclosed in JP2013-041566A, a touch panel is manufactured by bonding respective members (for example, a substrate, a conductive film for a touch sensor, and an antireflection film) to each other through an adhesive film such as an optical clear adhesive (OCA) film.

On the other hand, recently, a flexible display such as an organic electroluminescence display device (hereinafter, also referred to as “organic EL display device”) that can be bent, for example, can be curved, rounded, and folded has been actively developed (for example, JP2015-031953A), and flexibility has been desired for a touch panel into which the flexible display is incorporated.

### SUMMARY OF THE INVENTION

The present inventors manufactured a flexible device on which the touch panel described in JP2013-041566A was mounted and conducted an investigation on a flexible device. As a result, it was found that peeling between members in the touch panel is likely to occur in a bent portion during bending. In a case where peeling between members occurs, the touch panel may break, or a wiring disposed in the touch panel may be disconnected.

Therefore, an object of the present invention is to provide a laminate for a touch panel in which peeling between members is not likely to occur in a bent portion during bending.

In addition, another object of the present invention is to provide a flexible device and an organic electroluminescence display device that include the above-described laminate for a touch panel.

The present inventors conducted a thorough investigation in order to achieve the objects and found that the objects can be achieved with a laminate for a touch panel that includes an adhesive film having specific physical properties as a member, thereby completing the present invention.

That is, the present inventors found that the objects can be achieved with the following configurations.

(1) A laminate for a touch panel that is bendable, comprising a plurality of members,

in which at least one of the members is a member including a conductive portion,

at least one of the members is an adhesive film, and

the adhesive film has a 180 degree peel strength of 0.5 N/mm or higher with respect to an adjacent member and has a thickness of 30 μm or more.

(2) The laminate for a touch panel according to (1),

in which the 180 degree peel strength of the adhesive film with respect to the adjacent member is 0.6 N/mm or higher.

(3) The laminate for a touch panel according to (1) or (2), in which the thickness of the adhesive film is 50 μm or more.

(4) The laminate for a touch panel according to any one of (1) to (3),

in which at least two of the members are adhesive films, and

the adhesive film with the largest curvature among the adhesive films in a case where the laminate for a touch panel is bent has a 180 degree peel strength of 0.5 N/mm or higher with respect to an adjacent member and has a thickness of 30 μm or more.

(5) The laminate for a touch panel according to any one of (1) to (4),

in which the member including the conductive portion is a conductive film including a substrate and a conductive portion formed of a thin metal wire that is disposed on at least one surface of the substrate.

(6) The laminate for a touch panel according to (5),

in which the conductive portion is disposed on opposite surfaces of the substrate.

(7) The laminate for a touch panel according to (5) or (6),

in which the thin metal wire contains silver.

(8) The laminate for a touch panel according to any one of (5) to (7),

in which the thin metal wire contains a binder.

(9) An organic electroluminescence display device comprising:

the laminate for a touch panel according to any one of (1) to (8); and

a light emitting portion including a light emitting layer and electrodes between which the light emitting layer is interposed.

(10) A flexible device comprising:

the laminate for a touch panel according to any one of (1) to (8).

According to the present invention, a laminate for a touch panel in which peeling between members is not likely to occur in a bent portion during bending can be provided.

In addition, according to the present invention, a flexible device and an organic electroluminescence display device that include the above-described laminate for a touch panel can be provided.

### BRIEF DESCRIPTION OF THE DRAWINGS

FIG. 1 is a schematic cross-sectional view illustrating an example of an embodiment of a laminate for a touch panel according to the present invention.

FIG. 2 is a schematic cross-sectional view illustrating a state where the laminate for a touch panel illustrated in FIG. 1 is curved.

FIG. 3 is a plan view illustrating a conductive film 12 for a touch sensor.

FIG. 4 is a cross-sectional view taken along line A-A of FIG. 3.

FIG. 5 is an enlarged plan view illustrating first detecting electrodes.

FIG. 6 is a schematic cross-sectional view illustrating an example of an embodiment of an organic EL display device according to the present invention.

### DESCRIPTION OF THE PREFERRED EMBODIMENTS

[Laminate for Touch Panel]

Hereinafter, the details of the present invention will be described.

The following description regarding components has been made based on a representative embodiment of the present invention. However, the present invention is not limited to the embodiment.

In this specification, numerical ranges represented by “to” include numerical values before and after “to” as lower limit values and upper limit values.

In addition, in this specification, “light” denotes an actinic ray or radiation. In his specification, unless specified otherwise, “exposure” denotes not only exposure using a bright light spectrum of a mercury lamp, a far ultraviolet ray represented by excimer laser, an X-ray, an EUV ray, or the like but also drawing using a corpuscular beam such as an electron beam or an ion beam.

In addition, in this specification, (meth)acryl) denotes either or both of acryl and methacryl.

[Laminate for Touch Panel]

A laminate for a touch panel according to an embodiment of the present invention is obtained by laminating a plurality of members and is bendable. This laminate is characterized in that at least one adhesive film included as the member has a 180 degree peel strength of 0.5 N/mm or higher with respect to an adjacent member and has a thickness of 30 μm or more.

Hereinafter, embodiments of the present invention will be described in detail using the drawings.

### First Embodiment

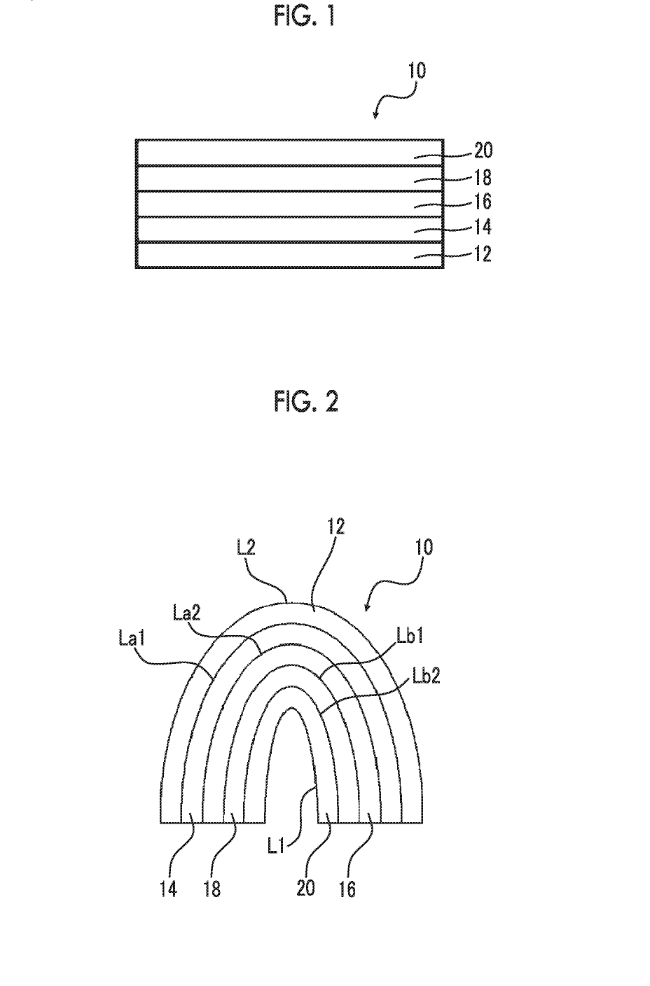

FIG. 1 is a schematic cross-sectional view illustrating an example of an embodiment of the laminate for a touch panel according to the present invention. The drawing in the present invention is a schematic diagram, and a thickness relationship and a positional relationship between respective layers do not necessarily match the actual ones. The same shall be applied to the following drawings.

A laminate 10 for a touch panel comprises, as the members: a conductive film 12 for a touch sensor that is a member including a conductive portion; an antireflection film 16; a protective film 20; an adhesive film 14 that is disposed between the conductive film 12 for a touch sensor and the antireflection film 16; an adhesive film 18 that is disposed between the antireflection film 16 and the protective film 20.

The adhesive film 14 has a 180 degree peel strength of 0.5 N/mm or higher with respect to the conductive film 12 for a touch sensor and the antirefiection film 16 that are adjacent members. In addition, the adhesive film 14 has a thickness of 30 μm or more. The adhesive film 18 has a 180 degree peel strength of 0.5 N/mm or higher with respect to the antireflection film 16 and the protective film 20 that are adjacent members. In addition, the adhesive film 18 has a thickness of 30 μm or more.

In the laminate for a touch panel according to the embodiment of the present invention, it is preferable that the conductive film for a touch sensor is positioned on the outermost layer side as illustrated in FIG. 1.

The 180 degree peel strength of the adhesive film 14 with respect to the conductive film 12 for a touch sensor can be obtained as follows.

(Measurement of 180 Degree Peel Strength)

(a) First Measurement Method

First, one surface of the adhesive film 14 (width: 2.5 cm, length: 5.0 cm, thickness: a predetermined value of 30 μm or more (the thickness of the adhesive film 14 in the laminate for a touch panel)) is bonded to a glass substrate, and another surface of the adhesive film 14 is bonded to the conductive film 12 for a touch sensor (width: 3 cm, length: 15 cm, thickness: a predetermined value (the thickness of the conductive film 12 for a touch sensor in the laminate for a touch panel)) as an adjacent member. When the conductive film 12 for a touch sensor is bonded, one end of the conductive film 12 for a touch sensor and one end of the adhesive film 14 are aligned. Next, the obtained sample is treated under conditions of temperature: 40° C. and pressure: 0.5 MPa for 20 minutes, and then another end (free end) of the conductive film 12 for a touch sensor is gripped and pulled using AUTOGRAPH AGS-X (manufactured by Shimadzu. Corporation) in a 180 degree direction (speed: 300 mm/min) to measure the 180 degree peel strength. At this time, a value measured under conditions where peeling occurs at an interface between the conductive film 12 for a touch sensor and the adhesive film 14 or cohesion failure occurs in the adhesive film 14 is “the 180 degree peel strength of the adhesive film with respect to an adjacent member” described in the present invention. In order to perform the measurement as described above, it is desirable that the conductive film 12 for a touch sensor and the adhesive film 14 slightly peel off from each other in the end portion where the free end side of the conductive film 12 for a touch sensor and the adhesive film 14 are bonded to each other.

In addition, the 180 degree peel strength of the adhesive film 14 with respect to the antireflection film 16, the 180 degree peel strength of the adhesive film 18 with respect to the antireflection film 16, and the 180 degree peel strength of the adhesive film 18 with respect to the protective film 20 are measured as described above. That is, the 180 degree peel strength is measured using a member adjacent to the adhesive film instead of the conductive film 12 for a touch sensor.

(b) Second Measurement Method

In a second method, the 180 degree peel strength is measured using a touch panel or a laminate for a touch panel that is manufactured in advance. For example, in order to measure the peel strength between adhesive film 14 and the conductive film 12 for a touch sensor in the touch panel on which the laminate 10 for a touch panel is mounted; first, all the members bonded to the conductive film 12 for a touch sensor on the opposite side of the adhesive film 14 peel off from the conductive film 12 for a touch sensor such that the conductive film 12 for a touch sensor is positioned on the outermost side. After peeling, the entire laminate 10 for a touch panel is cut into a width of 2.5 cm, an interface between the conductive film 12 for a touch sensor and the adhesive film 14 peel off from an end portion such that a free end consisting of only the conductive film 12 for a touch sensor is formed. Next, the protective film 20 side of the laminate 10 for a touch panel in which the free end is formed is bonded to glass using a double-sided tape to prepare a measurement sample, and the free end of the conductive film 12 for a touch sensor is gripped and pulled using AUTOGRAPH AGS-X manufactured by Shimadzu Corporation) in a 180 degree direction (speed: 300 mm/min) to measure the 180 degree peel strength. In addition, the 180 degree peel strength of the adhesive film 14 with respect to the antireflection film 16, the 180 degree peel strength of the adhesive film 18 with respect to the antireflection film 16, and the 180 degree peel strength of the adhesive film 18 with respect to the protective film 20 are measured as described above. That is, the 180 degree peel strength is measured using a member adjacent to the adhesive film instead of the conductive film 12 for a touch sensor. “The 180 degree peel strength of the adhesive film with respect to an adjacent member” described in this specification refers to a numerical value obtained using the first or second measurement method.

In addition, in order to measure the thickness of the adhesive film 14, not only a method of measuring the thickness of the adhesive film 14 after lamination but also the following measurement method can be used.

“The thickness of the adhesive film” described in this specification refers to a numerical value obtained using the above-described measurement method.

In addition, the thickness of the adhesive film 18 is also measured as described above.

(Thickness Measurement)

First, a cross-section of the laminate 10 for a touch panel is observed using a transmission electron microscope (TEM: “H7100FA”, manufactured by Hitachi High-Technologies Corporation). Next, an interface is determined using a contrast difference of the obtained image, and the thickness of the adhesive film 14 is measured.

With the above-described configuration, in a case where the laminate 10 for a touch panel is bent using various methods such as curving, rounding, or folding, peeling between members is not likely to occur in a bent portion.

FIG. 2 is a schematic cross-sectional view illustrating a state where the laminate 10 for a touch panel illustrated in FIG. 1 is curved.

As illustrated in FIG. 2, in a case where the laminate 10 for a touch panel is curved such that the protective film 20 is positioned on the inside, bending stress is generated in each of the members. In particular, higher compressive stress is generated at a portion of the laminate 10 for a touch panel having a higher curvature (at a portion having a smaller curvature radius). That is, in a bent portion closer to a surface L1 positioned on the inside during the curving of the laminate 10 for a touch panel, higher compressive stress is generated and peeling between members is more likely to occur.

In the laminate 10 for a touch panel, the thickness of the adhesive film 14 is 30 μm or more. As a result, it is presumed that bending stress generated in the conductive film 12 for a touch sensor and the antireflection film 16 as adjacent members is distributed such that a force applied to an interface La1 between the conductive film 12 for a touch sensor and the adhesive film 14 and a force applied to an interface La2 between the adhesive film 14 and the antireflection film 16 are relaxed. In addition, the thickness of the adhesive film 18 is 30 μm or more. As a result, it is presumed that bending stress generated in the antireflection film 16 and the protective film 20 as adjacent members is distributed such that a force applied to an interface Lb1 between the antireflection film 16 and the adhesive film 18 and a force applied to an interface Lb2 between the adhesive film 18 and the protective film 20 are relaxed.

Further, the adhesive film 14 has a 180 degree peel strength of 0.5 N/mm or higher with respect to the conductive film 12 for a touch sensor and the antireflection film 16 that are adjacent members. As a result, adhesiveness between the conductive film 12 for a touch sensor and the antireflection film 16 is excellent. In addition, the adhesive film 18 has a 180 degree peel strength of 0.5 N/mm or higher with respect to the antireflection film 16 and the protective film 20 as adjacent members. As a result, adhesiveness between the antireflection film 16 and the protective film 20 is excellent. It is presumed that this excellent adhesiveness contributes to the effect of suppressing peeling between members in a bent portion.

Since the above-described effects synergistically act, the laminate 10 for a touch panel exhibits the effect of suppressing peeling between members in a bent portion during bending. This can be clarified from the results of Examples described below.

The thicknesses of the adhesive film 14 and the adhesive film 18 are 30 μm or more as described above and, from the viewpoint of further improving the effect of the present invention, are preferably 50 μm or more. On the other hand, in a case where the thicknesses of the adhesive film 14 and the adhesive film 18 are excessively large, the total thickness of the laminate 10 for a touch panel increases. As a result, during the curving of the laminate 10 for a touch panel, compressive stress on the surface L1 side positioned on the inside and tensile stress on a surface L2 side positioned on the outside increase, respectively. Therefore, the upper limit of the thicknesses of the adhesive film 14 and the adhesive film 18 is preferably 145 μm or less, more preferably 95 μm or less, and still more preferably 70 μm or less.

The 180 degree peel strength of the adhesive film 14 with respect to the conductive film 12 for a touch sensor and the antireflection film 16 and the 180 degree peel strength of the adhesive film 18 with respect to the antireflection film 16 and the protective film 20 are preferably 0.6 N/mm or higher from the viewpoint of further improving the effect of the present invention. Although the upper limit is not particularly limited, as the 180 degree peel strength of the adhesive film increases, the adhesive film tends to be flexible. Therefore, from the viewpoint of appropriately adjusting the mechanical strength of the laminate 10 for a touch panel, the 180 degree peel strength is preferably 1.5 N/mm or lower.

Hereinafter, each of the members forming the laminate 10 for a touch panel will be described in detail.

<Adhesive Film>

The adhesive films 14 and 18 are not particularly limited as long as they have a 180 degree peel strength of 0.5 N/mm or higher with respect to an adjacent member and have a thickness of 30 μm or more.

As a specific material forming the adhesive films 14 and 18, a (meth)acrylic pressure sensitive adhesive is preferable from the viewpoint of light fastness.

The 180 degree peel strength of the adhesive films 14 and 18 with respect to an adjacent member is determined depending on the material and composition of the adhesive films, a film state of the adhesive films, the kind of the adjacent member, and the like. The kind of the adjacent member may be selected depending on folding properties, module performance, and the like. However, from the viewpoint of adhesiveness with the (meth)acrylic pressure sensitive adhesive, for example, it is preferable that the adjacent member is formed of a material such as triacetyl cellulose (TAC), a (meth)acrylic resin, polyethylene terephthalate (PET), polyimide, or polyamide.

Regarding the elastic modulus of the adhesive films 14 and 18, from the viewpoints of promoting the distribution of bending stress and further suppressing peeling, the tensile elastic modulus (100 kHz) is preferably 1 MPa or lower, more preferably 0.6 MPa or lower, and still more preferably 0.3 MPa or lower.

As the adhesive films 14 and 18, for example, MO-3015G, 3015H, or 3015I (all of which are manufactured by Lintec Corporation) can be used.

<Member including Conductive Portion>

The laminate 10 for a touch panel includes the conductive film 12 for a touch sensor as the member including a conductive portion.

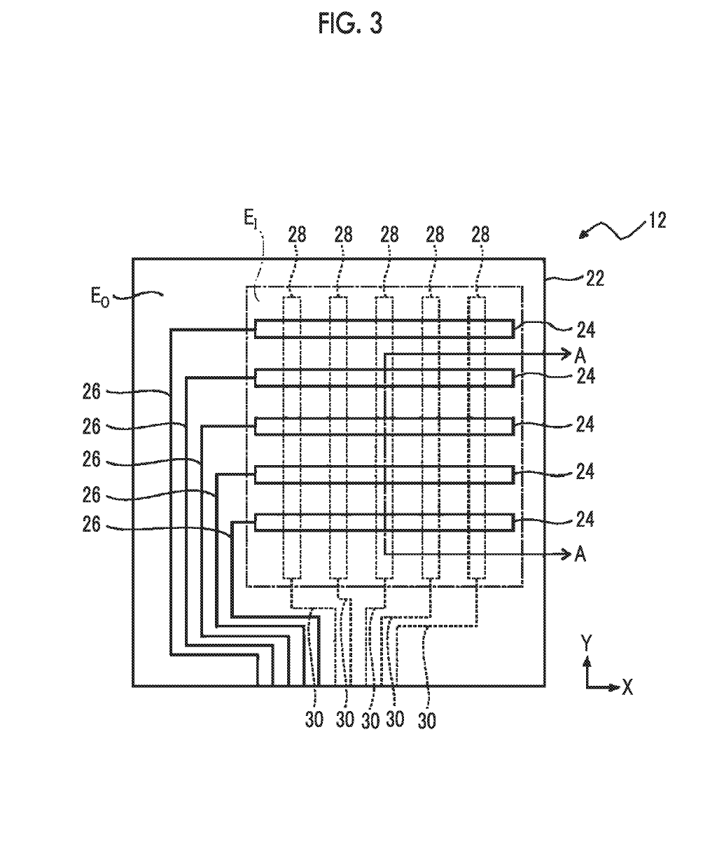

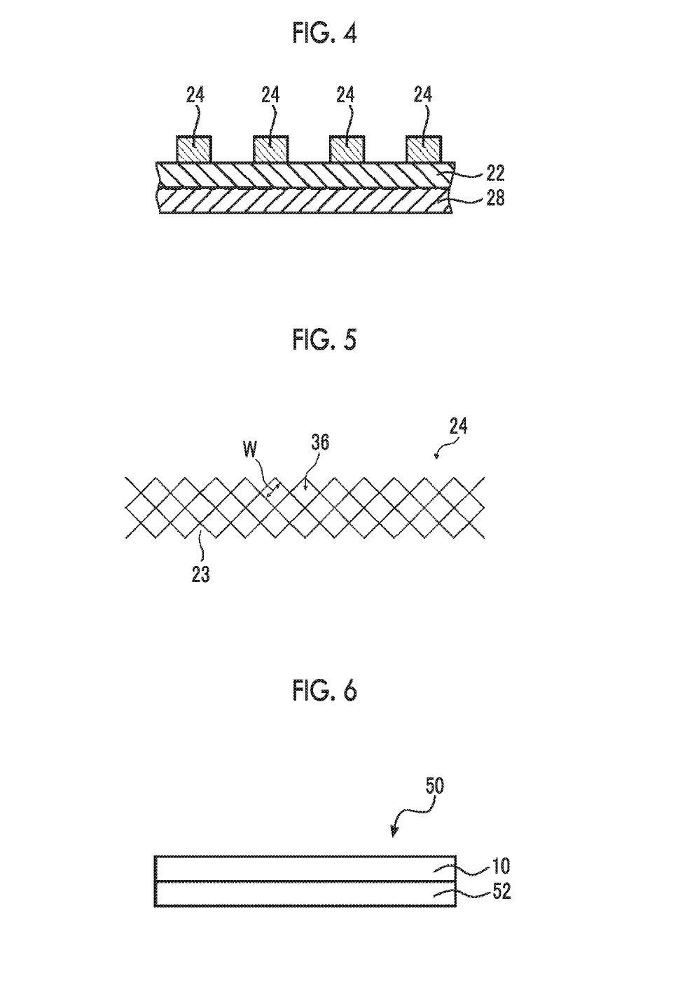

FIG. 3 is a plan view illustrating the conductive film 12 for a touch sensor. FIG. 4 is a cross-sectional view taken along line A-A of FIG. 3. The conductive film 12 for a touch sensor comprises: a substrate 22; a plurality of first detecting electrodes 24 that are disposed on one main surface (front surface) of the substrate 22; a plurality of first lead-out wirings 26; a plurality of second detecting electrodes 28 that are disposed on another main surface (back surface) of the substrate 22; and a plurality of second lead-out wirings 30.

A region where the first detecting electrodes 24 and the second detecting electrodes 28 are present constitutes an input region E₁ (input region (sensing portion) where contact of an object can be detected) where an input operation can be performed by a user. In an outside region E_{O} positioned outside of the input region E₁, the first lead-out wirings 26 and the second lead-out wirings 30 are disposed. The first lead-out wirings 26 and the second lead-out wirings 30 can be electrically connected to a flexible printed wiring board.

The first detecting electrodes 24, the first lead-out wirings 26, the second detecting electrodes 28 and the second lead-out wirings 30 of the conductive film 12 for a touch sensor correspond to the conductive portion.

The substrate 22 is a member that functions to support the first detecting electrodes 24 and the second detecting electrodes 28 in the input region E₁ and functions to support the first lead-out wirings 26 and the second lead-out wirings 30 in the outside region E_{O}.

The kind of the substrate 22 is not particularly limited as long as it can support the conductive portion. As the substrate 22, a transparent substrate is preferable, and a plastic film is more preferable.

As a specific example of a material forming the substrate 22, triacetyl cellulose (TAC), polyethylene terephthalate (PET), polyimide (PI), polycycloolefin (COP), a polycycloolefin copolymer (COC), polycarbonate, a (meth)acrylic resin, polyethylene naphthalate (PEN), polyethylene (PE), polypropylene (PP), polystyrene, polyvinyl chloride, or poly vinylidene chloride is preferable, TAC, PET, PI, COP, or COC is more preferable, and PET or COP is still more preferable.

It is preferable that the plastic film has a melting point of about 290° C. or lower.

The total light transmittance of the substrate 22 is preferably 85% to 100%.

The thickness of the substrate 22 is not particularly limited and, typically any value in a range of 25 to 500 μm can be selected. For bending, it is preferable that the thickness of the substrate 22 is small. Therefore, the thickness of the substrate 22 is preferably 25 to 80 μm, more preferably 25 to 60 μm, and still more preferably 25 to 40 μm.

In another preferable aspect of the substrate, it is preferable that an undercoat layer including a polymer is provided on a surface of the substrate. By forming the conductive portion on the undercoat layer, adhesiveness of the conductive portion is further improved.

A method of forming the undercoat layer is not particularly limited, and examples thereof include a method of applying an undercoat layer-forming composition including a polymer to the substrate and optionally performing a heat treatment thereon. Optionally, the undercoat layer-forming composition may include a solvent. The kind of the solvent is not particularly limited. For example, a well-known solvent is used. In addition, as the undercoat layer-forming composition including a polymer, a latex including polymer fine particles may be used.

The thickness of the undercoat layer is not particularly limited and, from the viewpoint of further improving adhesiveness with the conductive portion, is preferably 0.02 to 0.3 μm and more preferably 0.03 to 0.2 μm.

The first detecting electrodes 24 and the second detecting electrodes 28 are sensing electrodes that sense a change in capacitance and constitute a sensor portion. That is, in a case where a finger tip is brought into contact with a touch panel, the mutual capacitance between the first detecting electrodes 24 and the second detecting electrodes 28 changes, and the position of the fingertip is calculated by an integrated circuit (IC circuit) based on the amount of change.

The first detecting electrodes 24 function to detect an input position in an X direction of a finger of a user that approaches the input region E₁ and have a function of generating a capacitance with the finger. The first detecting electrodes 24 are electrodes that extend in a first direction (X direction) and are arranged in a second direction (Y direction) perpendicular to the X direction at predetermined intervals, and include a predetermined pattern as described above.

The second detecting electrodes 28 function to detect an input position in the Y direction of a finger of a user that approaches the input region E₁ and have a function of generating a capacitance with the finger. The second detecting electrodes 28 are electrodes that extend in the second direction (Y direction) and are arranged in the first direction (X direction) at predetermined intervals, and include a predetermined pattern as described above.

In FIG. 3, five first detecting electrodes 24 and five second detecting electrodes 28 are provided, and the numbers are not particularly limited as long as they are plural.

In FIG. 3, the first detecting electrodes 24 and the second detecting electrodes 28 are formed of thin metal wires. FIG. 5 is an enlarged plan view illustrating a part of the first detecting electrodes 24. As illustrated in FIG. 5, the first detecting electrodes 24 are formed of a thin metal wire 23 and include a plurality of openings 36 formed by thin metal wires 23 intersecting each other. As in the case of the first detecting electrodes 24, the second detecting electrodes 28 also include a plurality of openings 36 formed by the thin metal wires 23 intersecting each other. That is, the first detecting electrodes 24 and the second detecting electrodes 28 correspond to the conductive portion and have a mesh pattern formed of a plurality of thin metal wires.

The first lead-out wirings 26 and the second lead-out wirings 30 are members that function to apply voltages to the first detecting electrodes 24 and the second detecting electrodes 28, respectively.

The first lead-out wiring 26 is disposed on the substrate 22 on the outside region E_{O}, one end thereof is electrically connected to the corresponding first detecting electrode 24, and another end thereof is electrically connected to the flexible printed wiring board.

The second lead-out wiring 30 is disposed on the substrate 22 on the outside region E_{O}, one end thereof is electrically connected to the corresponding second detecting electrode 28, and another end thereof is electrically connected to the flexible printed wiring board.

In FIG. 3, five first lead-out wirings 26 and five second lead-out wirings 30 are provided, but the numbers thereof are not particularly limited. Typically, a plurality of first lead-out wirings 26 and a plurality of second lead-out wirings 30 are provided according to the numbers of the detecting electrodes.

The line width of the thin metal wire 23 is not particularly limited and is preferably 30 μm or less, more preferably 15 μm or less, still more preferably 10 μm or less, still more preferably 9 μm or less, and most preferably 7 μm or less and is preferably 0.5 μm or more and more preferably 1.0 μm or more. In a case where the line width is in the above-described range, an electrode having a low resistance can be relatively easily formed.

In a case where the thin metal wire is used as the lead-out wiring, the line width of the thin metal wire is preferably 500 μm or less, more preferably 50 μm or less, and still more preferably 30 μm or less. In a case where the line width is in the above-described range, a touch panel electrode having a low resistance can be relatively easily formed.

The thickness of the thin metal wire 23 is not particularly limited and is preferably 0.001 mm to 0.2 mm, more preferably 30 μm or less, still more preferably 20 μm or less, still more preferably 0.01 to 9 μm, and most preferably 0.05 to 5 μm. In a case where the thickness is in the above-described range, an electrode having a low resistance and excellent durability can be relatively easily formed.

The pattern formed of the thin metal wires 23 is not particularly limited to a mesh shape and may be a triangle such as a regular triangle, an isosceles triangle, or a right triangle, a quadrangle such as a square, a rectangle, a rhomboid, a parallelogram, or a trapezoid, a (regular) n-polygon such as a (regular) hexagon or a (regular) octagon, or a geometric figure as a combination of a circle, an ellipse, a star shape, and the like.

The mesh shape refers to a shape including a plurality of openings (lattice) 36 formed by the thin metal wires 23 intersection each other as illustrated in FIG. 5.

The openings 36 are open regions surrounded by the thin metal wires 23 One side length of the opening 36 is preferably 800 μm or less, more preferably 600 μm or less, and still more preferably 400 μm or less and is preferably 5 μm or more, more preferably 30 μm or more, and still more preferably 80 pin or more.

From the viewpoint of visible transmittance, the opening ratio is preferably 85% or higher, more preferably 90% or higher, and still more preferably 95% or higher. The opening ratio corresponds to an area ratio of transmitting portions (opening portions) excluding the thin metal wires to the entire conductive portion.

Examples of a metal contained in the thin metal wire 23 include a metal such as gold (Au), silver (Ag), copper (Cu), or aluminum (Al) and an alloy thereof. Among these, silver is preferable from the viewpoint of excellent conductivity of the thin metal wire.

From the viewpoint of adhesiveness between the thin metal wire and the substrate, it is preferable that the thin metal wire 23 contains a binder.

As the binder, a resin is preferable from the viewpoint of further improving adhesiveness between the thin metal wire and the substrate. For example, more specifically, at least one resin selected from the group consisting of a (meth)acrylic resin), a styrene resin, a vinyl resin, a polyolefin resin, a polyester resin, a polyurethane resin, a polyamide resin, a polycarbonate resin, a polydiene resin, an epoxy resin, a silicone resin, a cellulose polymer, and a chitosan polymer or a copolymer that is formed of monomers forming the resins can be used.

A method of manufacturing the thin metal wire 23 is not particularly limited, and a well-known method can be adopted. For example, a method of exposing and developing a photoresist film on a metal foil formed on a substrate surface to form a resist pattern and etching the exposed metal foil through the resist pattern can be used. In addition, a method of printing a paste containing metal fine particles or metal nanowires on opposite main surfaces of the substrate and plating the paste with metal can be used.

Further, in addition to the above-described methods, a method of using silver halide can be used. More specifically, a method described in paragraphs “0056” to “0114” of JP2014-209332A can be used.

In a preferable aspect of the conductive portion, the conductive portion includes a mesh pattern formed of thin silver wires from the viewpoint that the conductive portion is excellent in bending.

<Antireflection Film>

The antireflection film 16 includes a linearly polarizer and a λ/4 plate (a plate having a λ/4 function).

The antireflection film 16 is provided in the laminate 10 for a touch panel such that the λ/4 plate is disposed on the conductive film 12 side for a touch sensor and the polarizer is disposed on the protective film 20 side.

For example, in a case where the laminate 10 for a touch panel is disposed above a light emitting portion including a light emitting layer and electrodes between which the light emitting layer is interposed, light incident from the laminate 10 side for a touch panel passes through the linearly polarizer to be converted into linearly polarized light and then passes through the λ/4 plate to be converted into circularly polarized light. Next, the circularly polarized light is reflected from the electrode as described above to be converted into circularly polarized light having a turning direction opposite to that during the incidence. The reflected circularly polarized light passes through the λ/4 plate again to be converted into linearly polarized light that is polarized to be perpendicular to a transmission axis of the linearly polarizer, and thus cannot pass through the linearly polarizer. That is, since the antireflection film 16 is present, reflection of light incident from the outside into the laminate 10 for a touch panel is prevented.

FIG. 1 illustrates the single-layer λ/4 plate. However, a broadband λ/4 plate in which a λ/4 plate and a λ/2 plate are laminated may be used.

The linearly polarizer is not particularly limited as long as it is a member having a function of converting light into specific linearly polarized light, and an absorbing polarizer can be mainly used.

As the absorbing polarizer, for example, an iodine polarizer, a dye polarizer using a dichroic dye, or a polyene polarizer can be used. As the iodine polarizer and the dye polarizer, any one of a coating type polarizer or a stretching type polarizer can be used, and a polarizer manufactured by adsorbing iodine or a dichroic dye to polyvinyl alcohol and performing stretching is preferable.

In addition, examples of a method of obtaining a polarizer by performing stretching and dyeing on a laminated film in which a polyvinyl alcohol layer is formed on the substrate include methods described in JP5048120B, JP5143918B, JP4691205B, JP4751481B, and JP4751486B, and well-known techniques relating to the polarizers can be used.

The λ/4 plate is a plate having a function of converting linearly polarized light having a specific wavelength into circularly polarized light (or converting circularly polarized light into linearly polarized light). More specifically, the λ/4 plate is a plate in which an in-plane retardation value at a specific wavelength λ nm is λ/4 (or an odd number of times thereof).

The in-plane retardation value (Re(550)) of the λ/4 plate at a wavelength of 550 nm may have an error of about 25 nm from an ideal value (137.5 nm) and, for example, is preferably 110 to 160 nm, more preferably 120 to 150 nm, and still more preferably 130 to 145 nm.

An angle θ between an absorption axis of the polarizer and an in-plane slow axis of the λ/4 plate is preferably in a range of 45±3°. In other words, the angle θ is preferably in a range of 42° to 48°. From the viewpoint of further improving the antireflection effect, the angle θ is preferably in a range of 45±2°.

The angle refers to an angle between the absorption axis of the polarizer and the in-plane slow axis of the λ/4 plate in case of being seen from a normal direction of the surface of the polarizer (in other words, a front direction of an organic EL display device in FIG. 6 described below).

In a case where the broadband λ/4 plate is used as the λ/4 plate, it is preferable that the λ/4 plate and the λ/2 plate are bonded such that the angle between the in-plane slow axis of the λ/4 plate and the in-plane slow axis of the λ/2 plate is 60°, the λ/2 plate side is disposed on the incidence side of linearly polarized light, and the in-plane slow axis of the λ/2 plate intersects a polarization plane of incident linearly polarized light at 15° or 75°.

The angle refers to an angle between the absorption axis of the polarizer and the in-plane slow axis of the λ/4 plate and an angle between the absorption axis of the polarizer and the in-plane slow axis of the λ/2 plate in case of being seen from a normal direction of the surface of the polarizer (in other words, a front direction of an organic EL display device in FIG. 6 described below).

The thickness of the antireflection film is not particularly limited and is preferably 1 to 100 μm and more preferably 1 to 50 μm.

<Protective Film>

The protective film 20 functions to protect conductive film 12 for a touch sensor from an external environment, and a main surface thereof forms a touch surface.

As the protective film 20, a transparent substrate is preferable. For example, a plastic film or a plastic plate is used. It is desirable that the thickness of the protective film is appropriately selected according to the use thereof. For example, the thickness of the protective film is preferably 1 to 200 μm, more preferably 5 to 150 μm, and still more preferably 30 to 100 μm. In a case where the laminate is bent such that the protective film 20 is positioned on the inside and in a case where the thickness of the protective film 20 is 1 μm or more, the protective film 20 suppresses bending to the opposite side caused by compressive stress and suppresses peeling. In addition, in a case where the thickness of the protective film 20 is less than 200 μm, peeling is not likely to occur, and compressive stress is also suppressed. Therefore, buckling is not likely to occur. From the above-described viewpoint, it is preferable that the elastic modulus of the protective film 20 is also appropriately adjusted.

Examples of a raw material of the plastic film and the plastic plate include: a polyester such as polyethylene terephthalate (PET) or polyethylene naphthalate (PEN); a polyolefin such as polyethylene (PE), polypropylene (PP), polystyrene, or an ethylene-vinyl acetate copolymer (EVA); a vinyl resin; and other resins such as polycarbonate (PC), polyamide, polyimide, a (meth)acrylic resin, triacetyl cellulose (TAC), or a cycloolefin resin (COP).

The total thickness of the laminate 10 for a touch panel is not particularly limited. From the viewpoint of applying a flexible device that can be bent at a bending radius (curvature radius) of 5 mm or less, the total thickness of the laminate 10 for a touch panel is preferably 50 to 1200 μm and more preferably 100 to 600 μm.

### Second Embodiment

In addition, the first embodiment shows the aspect of the conductive film 12 for a touch sensor in which both the adhesive films 14 and 18 included in the laminate 10 for a touch panel have a 180 degree peel strength of 0.5 N/mm or higher with respect to an adjacent member and have a thickness of 30 μm or more. However, for example, only the adhesive film 18 may satisfy the above-described physical properties (second embodiment).

That is, in a case where the laminate for a touch panel according to the embodiment of the present invention includes a plurality of adhesive films, at least one adhesive film may have a 180 degree peel strength of 0.5 N/mm or higher with respect to an adjacent member and may have a thickness of 30 μm or more.

As illustrated in FIG. 2, in a bent portion closer to the surface L1 positioned on the inside during the curving of the laminate 10 for a touch panel, higher compressive stress is generated and peeling between members is more likely to occur. Therefore, even in a case where only the adhesive film 18 that is closest to the surface L1 positioned on the inside has the largest curvature during the bending of the laminate 10 for a touch panel satisfies the above-described physical properties, peeling between members can be effectively suppressed.

As the adhesive film 14, a commercially available product or a well-known product can be appropriately used.

### Third Embodiment

The first embodiment shows the configuration of the conductive film 12 for a touch sensor in which the conductive portion is formed on opposite surface of the substrate 22. However, for example, the conductive film 12 for a touch sensor may have a configuration in which the conductive portion is formed on a single surface of the substrate 22.

### Modification Example

In the first, second, and third embodiments, the example in which the laminate for a touch panel includes the conductive film for a touch sensor, the adhesive film, the antireflection film, the adhesive film, and the protective film as the members has been described. However, the laminate for a touch panel is not limited to this configuration.

For example, a laminate having a three-layer structure including the conductive film for a touch sensor, the adhesive film, and the protective film in this order may be adopted. In this case, the adhesive film may have a 180 degree peel strength of 0.5 N/mm or higher with respect to an adjacent member (the conductive film for a touch sensor or the protective film) and may have a thickness of 30 μm or more.

In addition, the laminate for a touch panel according to the embodiment of the present invention may include a member other than the above-described members. For example, the laminate for a touch panel may include a flexible printed wiring board that is electrically connected to the conductive film for a touch sensor.

The flexible printed wiring board is a plate in which a plurality of wirings and a plurality of terminals are provided on the substrate. For example, in FIG. 3, the other end of each of the first lead-out wirings 26 is connected to the other end of each of the second lead-out wirings 30 and functions to connect the conductive film 12 for a touch sensor and an external device (for example, a display panel) to each other.

[Use]

The laminate for a touch panel according to the embodiment of the present invention is applicable to a flexible device (for example, an organic EL display device) that can be bent, for example, can be curved, rounded, and folded. In particular, for example, in a case where the laminate for a touch panel according to the embodiment of the present invention is applied to a flexible device that can be bent at a bending radius (curvature radius) of preferably 5 mm or less, more preferably 3 mm or less, and still more preferably 2 mm or less, the effect of the present invention is significant.

[Organic EL Display Device]

An organic EL display device according to an embodiment of the present invention includes: the above-described laminate for a touch panel; and a light emitting portion including a light emitting layer (organic electroluminescence layer) and electrodes (a cathode and an anode) between which the light emitting layer is interposed. FIG. 6 is a schematic cross-sectional view illustrating an example of the embodiment of the organic EL display device according to the present invention. The drawing in the present invention is a schematic diagram, and a thickness relationship and a positional relationship between respective layers do not necessarily match the actual ones.

An organic EL display device 50 illustrated in FIG. 6 includes a light emitting portion 52 and the laminate 10 for a touch panel that is disposed on the light emitting portion 52. The laminate 10 for a touch panel is disposed on the light emitting portion 52 such that the conductive film 12 for a touch sensor faces the light emitting portion 52 through the adhesive film. The light emitting portion 52 refers to a so-called organic EL display panel and includes a display surface that displays an image. The configuration of the light emitting portion 52 is not particularly limited, and a well-known configuration of the organic EL display panel is adopted. In addition, as the adhesive film, a commercially available product can be used.

[Flexible Device]

A flexible device according to an embodiment of the present invention includes: the above-described laminate for a touch panel; and a display element having a display surface that displays an image.

The kind of the display element is not particularly limited, and a well-known display device can be used. Examples of the display element include an organic EL display device, a liquid crystal display device (LCD), a vacuum fluorescent display (VFD), a plasma display panel (PDP), a surface-conduction electron-emitter display (SED), a field emission display (FED), and an electronic paper (E-Paper). Among these, an organic EL display device or an electronic paper (E-Paper) is preferable.

### EXAMPLES

Hereinafter, the present invention will be described in more detail based on the following examples. Materials, used amounts, ratios, treatment details, treatment procedures, and the like shown in the following examples can be appropriately changed within a range not departing from the scope of the present invention. Accordingly, the scope of the present invention is not limited to the following examples.

### Example 1

«Preparation of Conductive Film A for Touch Sensor»

<Formation of Conductive Portion>

(Preparation of Silver Halide Emulsion)

The following solution 2 and the following solution 3 were simultaneously added for 20 minutes to the following solution 1 held at pH 4.5 and 38° C. in amounts corresponding to 90% of the entire amounts while stirring the solutions. As a result, nuclear particles having a size of 0.16 μm were formed. Next, the following solution 4 and the following solution 5 were added for 8 minutes, and the remaining 10% amounts of the solution 2 and the solution 3 were further added for 2 minutes. As a result, the nuclear particles grew to a size of 0.21 μm. Further, 0.15 g of potassium iodide was added, and the particles were aged for 5 minutes. Then the formation of the particles was completed.

Solution 1

Water: 750 ml

Gelatin: 8.6 g

Sodium chloride: 3 g

1,3-Dimethylimidazolidine-2-thione: 20 mg

Sodium benzenethiolsulfonate: 10 mg

Citric acid: 0.7 g

Solution 2

Water: 300 ml

Silver nitrate: 150 g

Solution 3

Water: 300 ml

Sodium chloride: 38 g

Potassium bromide: 32 g

Potassium hexachloroiridate(III) (0.005% KCl 20% aqueous solution): 5 ml

Ammonium hexachlororhodate (0.001% NaCl 20% aqueous solution): 7 ml

Solution 4

Water: 100 ml

Silver nitrate: 50 g

Solution 5

Water: 100 ml

Sodium chloride: 13 g

Potassium bromide: 11 g

Yellow prussiate of potash: 5 mg

Next, the particles were cleaned with water by flocculation using an ordinary method. Specifically, the temperature of the obtained solution was decreased to 35° C., and the pH was decreased (to be in a range of pH 3.6±0.2) using sulfuric acid until silver halide precipitated. Next, about 3 L of the supernatant liquid was removed (first water cleaning). Further, 3 L of distilled water was added, and sulfuric acid was added until silver halide precipitated. Next, about 3 L of the supernatant liquid was removed again (second water cleaning). By repeating the same operation as the second cleaning once more (third water cleaning), the water cleaning and desalting step was completed. After the water cleaning and desalting, the emulsion was adjusted to pH 6.4 and pAg 7.5, 2.5 g of gelatin, 10 mg of sodium henzenethiolsulfonate, 3 mg of sodium henzenethiosulfinate, 15 mg of sodium thiosulfate, and 10 mg of chloroauric acid were added, and chemosensitization was performed at 55° C. to obtain the optimum sensitivity. Next, 100 mg of 1,3,3a,7-tetraazaindene as a stabilizer and 100 mg of PROXEL (trade name, manufactured by ICI Co., Ltd.) as a preservative were further added. The finally obtained emulsion was a silver chloroiodobromide cubic particle emulsion having an average particle size of 0.22 μm and a coefficient of variation of 9%, in which the content of silver iodide was 0.08 mol %, and the ratio of silver chlorobromide was 70 mol % of silver chloride/30 mol % of silver bromide.

(Preparation of Composition for Forming Photosensitive Layer)

1.2×10⁻⁴ mol/mol Ag of 1,3,3a,7-tetraazaindene, 1.2×10⁻² mol/mol Ag of hydroquinone, 3.0×10⁴ mol/mol Ag of citric acid, 0.90 g/mol Ag of 2,4-dichloro-6-hydroxy-1,3,5-triazine sodium salt, and a small amount of a hardening agent were added to the emulsion, and the pH of the coating solution was adjusted to 5.6 using citric acid.

A polymer latex including a polymer represented by the following (P-1) and a dispersant formed of dialkylphenyl PEO (polyethylene glycol) sulfuric acid ester (a mass ratio dispersant/polymer was 2.0/100=0.02) was added to the coating solution such that a mass ratio polymer/gelatin of the polymer to the gelatin in the coating solution was 0.5/1.

Further, EPOXY RESIN DY022 (trade name, manufactured by Nagase ChemteX Corporation) as a crosslinking agent was added. The addition amount of the crosslinking agent was adjusted such that the amount of the crosslinking agent in the silver halide-containing photosensitive layer described below was 0.09 g/m².

This way, the composition for forming a photosensitive layer was prepared.

The polymer represented by (P-1) shown above as an example was synthesized with reference to JP3305459B and JP3754745B.

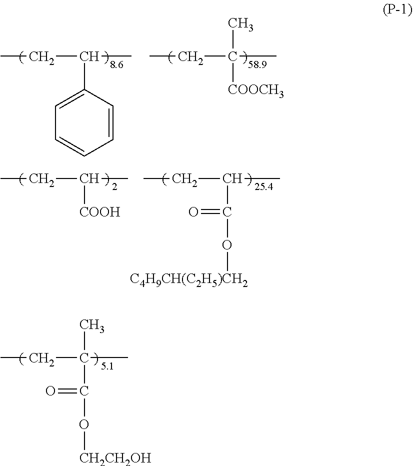

(Photosensitive Layer Forming Step)

The polymer latex was applied to a cycloolefin polymer (COP) film having a thickness of 60 μm to provide an undercoat layer having a thickness of 0.05 μm.

Next, a composition for forming a silver halide non-containing layer in which the polymer latex and gelatin were mixed with each other was applied to the undercoat layer to provide a silver halide non-containing layer having a thickness of 1.0 μm. The mixing mass ratio (polymer/gelatin) of the polymer to the gelatin was 2/1, and the content of the polymer was 0.65 g/m².

Next, the composition for forming a photosensitive layer was applied to the silver halide non-containing layer to provide a silver halide-containing photosensitive layer (hereinafter, also referred to as “photosensitive layer”) having a thickness of 2.5 μm. The mixing mass ratio (polymer/gelatin) of the polymer to the gelatin in the silver halide-containing photosensitive layer was 0.5/1, and the content of the polymer was 0.22 g/m².

Next, a composition for forming a protective layer in which the polymer latex and gelatin were mixed with each other was applied to the silver halide-containing photosensitive layer to provide a protective layer having a thickness of 0.15 μm. The mixing mass ratio (polymer/gelatin) of the polymer to the gelatin was 0.1/1, and the content of the polymer was 0.015 g/m².

(Exposing and Developing)

The photosensitive layer prepared as described above was exposed to parallel light emitted from a high pressure mercury lamp as a light source through a photomask capable of forming a developed silver image having a pattern of line/space=30 μm/30 μm (the number of lines was 20). After the exposure, the surface of the film was developed using the following developer, was developed using a fixing solution (trade name N3X-R for CN16X, manufactured by Fuji Film Co., Ltd.), was rinsed with pure water, and then was dried.

(Composition of Developer)

1 L of the developer included the following compounds.

Hydroquinone: 0.037 mol/L

N-methylamino phenol: 0.016 mol/L

Sodium metaborate: 0.140 mol/L,

Sodium hydroxide: 0.360 mol/L

Sodium bromide: 0.031 mol/L

Potassium metabisulfite: 0.187 mol/L

(Heat Treatment)

Further, the film was left to stand in a superheated steam bath at 120° C. for 130 seconds to heat the film.

(Gelatin Decomposition Treatment)

Further, the film was clipped in a gelatin decomposition solution (40° C.) prepared as described above for 120 seconds, was dipped in warm water (liquid temperature: 50° C.) for 120 seconds, and was cleaned.

Preparation of Gelatin Decomposition Solution

Triethanolamine and sulfuric acid were added to an aqueous solution (concentration of protease: 0.5 mass %) of protease (BIOPRASE 30 L, manufactured by Nagase CheniteX Corporation) to adjust the pH to 8.5.

(Polymer Crosslinking Treatment)

Further, the film was dipped in a CARBODILITE V-02-L2 (trade name: manufactured by Nisshinbo Chemical Inc.) 1% aqueous solution for 30 seconds, was extracted from the aqueous solution, was dipped in pure water (room temperature) for 60 seconds, and was cleaned.

This way, a conductive film A for a touch sensor in which the conductive portion formed of the thin silver wire pattern was formed on the COP film was obtained.

«Preparation of Laminate for Touch Panel»

By laminating the respective members according to the following configuration, a laminate for a touch panel was prepared (refer to FIG. 3).

Protective film/Adhesive Film (Top)/Antireflection Film/Adhesive Film (Middle)/Conductive film for Touch Sensor

“Material” and “thickness” of each of the members are shown in Table 1.

In addition, as the antireflection film, an antireflection film including a linearly polarizer and a broadband λ/4 plate was used. The broadband λ/4 plate was a laminate in which a λ/4 plate and a λ/2 plate were laminated. Specifically, an optical laminate described in Example 1 of WO2013/137464A was prepared according to the same procedure and was set as an antireflection film A. The antireflection film A was disposed such that the linearly polarizer was positioned on the adhesive film (Top) side and the λ/4 plate was positioned on the adhesive film (Middle) side.

(180 Degree Peel Strength)

The 180 degree peel strength of the adhesive film (Top) with respect to an adjacent member and the 180 degree peel strength of the adhesive film (Middle) with respect to an adjacent member were measured based on the above-described measurement method of “180 Degree Peel Strength”. Table 1 shows the respective values.

«Preparation of Flexible Device»

The laminate for a touch panel obtained as described above was bonded to a display laminate prepared simulating a display panel through an adhesive film (Bottom) (“8146-2” (trade name, “manufactured by 3M”), thickness: 50 μm). As a result, a flexible device was prepared by simulation. The display laminate had a configuration in which a polyimide film (KAPTON (trade name), “manufactured by Du Pont-Toray Co., Ltd.”) having a thickness of 30 μm and a polyimide film (KAPTON (trade name), “manufactured by Du Pont-Toray Co., Ltd.”) having a thickness of 125 μm were bonded to each other through an adhesive film “8146-1” (trade name. “manufactured by 3M”) having a thickness of 25 μm.

(180 Degree Peel Strength)

The 180 degree peel strength of the adhesive film (Bottom) with respect to an adjacent member was measured based on the above-described measurement method of “180 Degree Peel Strength”, FIG. 1 shows the values.

«Evaluation»

The obtained flexible device was treated using an autoclave under conditions of temperature: 40° C. and pressure: 0.5 MPa for 20 minutes. Next, the treated flexible device was tested 10000 times in a bending test using a folding test machine (Tension free u-shape folding test machine; DLDMLH-FS, manufactured by Yuasa Co., Ltd.)

In the folding test machine, the distance between guides was set as 6 mm.

In addition, a folding direction was set such as a surface positioned on the inside during the folding of the flexible device faced the protective film.

The flexible device that was tested 10000 times in the folding test was evaluated based on the following criteria from the viewpoints of “Breakage of Flexible Device”, “Peeling between Members”, and “Disconnection of Conductive portion in Conductive Film for Touch Sensor”. It is presumed that, in the folding test, peeling was likely to occur particularly on the protective film side positioned on the inside during the folding of the flexible device. Therefore, in a peel test, peeling between the adhesive film (Top) and the protective film and peeling between the adhesive film (Top) and the antireflection film were evaluated. In addition, the evaluation of breakage and the evaluation of peeling were performed by visual inspection.

The results are shown in Table 1.

(Breakage)

“3”: breakage did not occur in a bent portion

“2”: breakage occurred at a part of the materials in a bent portion

“1”: breakage occurred in the entire area of a bent portion

(Peeling)

“4”: peeling did not occur in a bent portion

“3”: peeling occurred at a small portion either between the adhesive film (Top) and the protective film or between the adhesive film (Top) and the antireflection film in a bent portion

“2”: peeling partially occurred at least either between the adhesive film (Top) and the protective film or between the adhesive film (Top) and the antireflection film in a bent portion

“1”: peeling entirely occurred at least either between the adhesive film (Top) and the protective film or between the adhesive film (Top) and the antireflection film in a bent portion, but peeling did not occur by folding the flexible device once

“0”: peeling entirely occurred at least either between the adhesive film (Top) and the protective film or between the adhesive film (Top) and the antireflection film in a bent portion, and peeling occurred by folding the flexible device once

(Disconnection)

“4”: the resistance did not substantially increase (an increase in resistance value was 100 or higher and lower than 300 Ohm, and disconnection did not also occur)

“3”: the resistance increased (an increase in resistance value was 300 to 10000 Ohm, but disconnection did not occur)

“2”: the resistance increased (an increase in resistance Value was higher than 10000 Ohm, but disconnection did not occur)

“1”: the resistance increased (disconnection partially occurred)

“0”: the resistance increased (disconnection entirely occurred)

### Examples 2 to 15 and Comparative Examples 1 to 8

Flexible devices according to Examples 2 to 15 and Comparative Examples 1 to 8 were prepared using the same method as that of Example 1, except that the configuration of the respective members was changed as shown in Table 1. The evaluation was performed using the same method as that of Example 1. The results are shown in Table 1.

Conductive films B to D for a touch sensor used in Examples 4, 5, and 6 and Comparative Examples 6, 7, and 8 were prepared using the following method.

«Preparation of Conductive Film B for Touch Sensor»

The same pattern as the thin wire pattern prepared in Example 1 was formed on a transparent conductive film (an indium tin oxide (ITO) film, “ELECRYSTA”, manufactured by Nitto Denko Corporation) using a typical photolithography method. As a result, a film (conductive film B for a touch sensor) including a conductive portion on the substrate was prepared.

«Preparation of Conductive Film C for Touch Sensor»

First, a Ni layer having a thickness of 5 nm was formed on the cycloolefin polymer (COP) film using a sputtering method, and copper was vapor-deposited on thereon using a vacuum deposition method by resistance heating to form a Cu flat film having a thickness of 2 μm. Next, the same pattern as the thin wire pattern prepared using Example 1 was formed using a typical photolithography method. As a result, a film (conductive film C for a touch sensor) including a conductive portion formed of a Cu pattern on the substrate was prepared.

«Preparation of Conductive Film D for Touch Sensor»

A coating film having a thickness of 1 μm was formed on a cycloolefin polymer (COP) film using Ag nanowires according to a method described in JP2009-215594A. Next, the same pattern as the thin wire pattern prepared using Example 1 was formed using a typical photolithography method. As a result, a film (conductive film D for a touch sensor) including a conductive portion formed of Ag wires on the substrate was prepared.

Hereinafter, Table 1 will be shown.

In Table 1, “PET” represents polyethylene terephthalate, and “PI” represents polyimide.

TABLE 1

| | | Example 1 | Example 2 | Example 3 | Example 4 | Example 5 | Example 6 |
|---|---|---|---|---|---|---|---|
| Protective | Kind | PET | PET | PI | PET | PET | PET |
| Film | Thickness (μm) | 40 | 40 | 50 | 40 | 40 | 40 |
| Adhesive | Kind | MO-3015G | MO-3015H | MO-3015G | MO-3015G | MO-3015G | MO-3015G |
| Film | | (manufactured | (manufactured | (manufactured | (manufactured | (manufactured | (manufactured |
| (Top) | | by Lintec | by Lintec | by Lintec | by Lintec | by Lintec | by Lintec |
| | | Corporation) | Corporation) | Corporation) | Corporation) | Corporation) | Corporation) |
| | Thickness (μm) | 50 | 75 | 50 | 50 | 50 | 50 |
| | Adhesive Strength (N/mm) | 0.51 | 0.68 | 0.9 | 0.51 | 0.51 | 0.51 |
| | between Protective Film | | | | | | |
| | and Adhesive Film (Top) | | | | | | |
| | Adhesive Strength (N/mm) | 0.66 | 0.78 | 0.66 | 0.66 | 0.66 | 0.66 |
| | between Adhesive Film (Top) | | | | | | |
| | and Antireflection Film | | | | | | |
| Anti- | Kind | A | A | A | A | A | A |
| reflection | Thickness (μm) | 40 | 40 | 40 | 40 | 40 | 40 |
| Film | | | | | | | |
| Adhesive | Kind | MO-3015G | MO-3015G | MO-3015G | MO-3015G | MO-3015G | MO-3015G |
| Film | | (manufactured | (manufactured | (manufactured | (manufactured | (manufactured | (manufactured |
| (Middle) | | by Lintec | by Lintec | by Lintec | by Lintec | by Lintec | by Lintec |
| | | Corporation) | Corporation) | Corporation) | Corporation) | Corporation) | Corporation) |
| | Thickness (μm) | 50 | 50 | 50 | 50 | 50 | 50 |
| | Adhesive Strength (N/mm) | 0.66 | 0.66 | 0.66 | 0.66 | 0.66 | 0.66 |
| | between Antireflection Film | | | | | | |
| | and Adhesive Film (Middle) | | | | | | |
| | Adhesive Strength (N/mm) | 0.55 | 0.55 | 0.55 | 0.67 | 0.58 | 0.62 |
| | between Adhesive Film (Middle) | | | | | | |
| | and Conductive Film for Touch | | | | | | |
| | Sensor | | | | | | |
| Conductive | Kind | A | A | A | B | C | D |
| Film for | | (Ag Mesh) | (Ag Mesh) | (Ag Mesh) | (ITO THIN | (Cu Mesh) | (Ag |
| Touch | | | | | FILM) | | Nanowire) |
| Sensor | | | | | | | |
| Adhesive | Kind | 8146-2 | 8146-2 | 8146-2 | 8146-2 | 8146-2 | 8146-2 |
| Film | | (Manufactured | (Manufactured | (Manufactured | (Manufactured | (Manufactured | (Manufactured |
| (Bottom) | | by 3M) | by 3M) | by 3M) | by 3M) | by 3M) | by 3M) |
| | Thickness (μm) | 50 | 50 | 50 | 50 | 50 | 50 |
| | Adhesive Strength (N/mm) | 0.31 | 0.31 | 0.31 | 0.31 | 0.31 | 0.31 |
| | between Conductive Film for | | | | | | |
| | Touch Sensor and | | | | | | |
| | Adhesive Film (Bottom) | | | | | | |
| | Adhesive Strength (N/mm) | 0.48 | 0.48 | 0.48 | 0.48 | 0.48 | 0.48 |
| | between Adhesive Film (Bottom) | | | | | | |
| | and Display Laminate | | | | | | |
| Display | Kind | KAPTON (30 | KAPTON (30 | KAPTON (30 | KAPTON (30 | KAPTON (30 | KAPTON (30 |
| Laminate | | μm)/8146-1 | μm)/8146-1 | μm)/8146-1 | μm)/8146-1 | μm)/8146-1 | μm)/8146-1 |
| | | (manufactured | (manufactured | (manufactured | (manufactured | (manufactured | (manufactured |
| | | by 3M | by 3M | by 3M | by 3M | by 3M | by 3M |
| | | Company, 25 | Company, 25 | Company, 25 | Company, 25 | Company, 25 | Company, 25 |
| | | μm)/KAPTON | μm)/KAPTON | μm)/KAPTON | μm)/KAPTON | μm)/KAPTON | μm)/KAPTON |
| | | (125 μm) | (125 μm) | (125 μm) | (125 μm) | (125 μm) | (125 μm) |
| Evaluation | Breakage | 3 | 3 | 3 | 3 | 3 | 3 |
| | Peeling (Protective Film, | 4 | 4 | 4 | 4 | 4 | 4 |
| | Antireflection Film) | | | | | | |
| | Disconnection (Conductive | 4 | 4 | 4 | 2 | 2 | 4 |
| | Portion in Touch Sensor Film) | | | | | | |
| | | Example 7 | Example 8 | Example 9 | Example 10 | Example 11 | Example 12 |
| Protective | Kind | PET | PET | PET | PET | PET | PET |
| Film | Thickness (μm) | 40 | 40 | 40 | 40 | 40 | 40 |
| Adhesive | Kind | MO-3015I | Two Layers | MO-3015G | MO-3015G | MO-3015G | MO-3015G |
| Film | | (manufactured | of MO-3015G | (manufactured | (manufactured | (manufactured | (manufactured |
| (Top) | | by Lintec | and | by Lintec | by Lintec | by Lintec | by Lintec |
| | | Corporation) | MO-3015I | Corporation) | Corporation) | Corporation) | Corporation) |
| | | | (manufactured | | | | |
| | | | by Lintec | | | | |
| | | | Corporation) | | | | |
| | Thickness (μm) | 100 | 150 | 50 | 50 | 50 | 50 |
| | Adhesive Strength (N/mm) | 0.78 | 0.82 | 0.51 | 0.51 | 0.51 | 0.51 |
| | between Protective Film | | | | | | |
| | and Adhesive Film (Top) | | | | | | |
| | Adhesive Strength (N/mm) | 0.82 | 0.85 | 0.66 | 0.66 | 0.66 | 0.66 |
| | between Adhesive Film (Top) | | | | | | |
| | and Antireflection Film | | | | | | |
| Anti- | Kind | A | A | A | A | A | A |
| reflection | Thickness (μm) | 40 | 40 | 40 | 40 | 40 | 40 |
| Film | | | | | | | |
| Adhesive | Kind | MO-3015G | MO-3015G | MO-3015C | 8146-2 | MO-3015H | MO-3015I |
| Film | | (manufactured | (manufactured | (manufactured | (Manufactured | (manufactured | (manufactured |
| (Middle) | | by Lintec | by Lintec | by Lintec | by 3M) | by Lintec | by Lintec |
| | | Corporation) | Corporation) | Corporation) | | Corporation) | Corporation) |
| | Thickness (μm) | 50 | 50 | 25 | 50 | 75 | 100 |
| | Adhesive Strength (N/mm) | 0.66 | 0.66 | 0.42 | 0.27 | 0.69 | 0.71 |
| | between Antireflection Film | | | | | | |
| | and Adhesive Film (Middle) | | | | | | |
| | Adhesive Strength (N/mm) | 0.55 | 0.55 | 0.42 | 0.31 | 0.82 | 0.84 |
| | between Adhesive Film (Middle) | | | | | | |
| | and Conductive Film for Touch | | | | | | |
| | Sensor | | | | | | |
| Conductive | Kind | A | A | A | A | A | A |
| Film for | | (Ag Mesh) | (Ag Mesh) | (Ag Mesh) | (Ag Mesh) | (Ag Mesh) | (Ag Mesh) |
| Touch | | | | | | | |
| Sensor | | | | | | | |
| Adhesive | Kind | 8146-2 | 8146-2 | 8146-2 | 8146-2 | 8146-2 | 8146-2 |
| Film | | (Manufactured | (Manufactured | (Manufactured | (Manufactured | (Manufactured | (Manufactured |
| (Bottom) | | by 3M) | by 3M) | by 3M) | by 3M) | by 3M) | by 3M) |
| | Thickness (μm) | 50 | 50 | 50 | 50 | 50 | 50 |
| | Adhesive Strength (N/mm) | 0.31 | 0.31 | 0.31 | 0.31 | 0.31 | 0.31 |
| | between Conductive Film for | | | | | | |
| | Touch Sensor and | | | | | | |
| | Adhesive Film (Bottom) | | | | | | |
| | Adhesive Strength (N/mm) | 0.48 | 0.48 | 0.48 | 0.48 | 0.48 | 0.48 |
| | between Adhesive Film (Bottom) | | | | | | |
| | and Display Laminate | | | | | | |
| Display | Kind | KAPTON (30 | KAPTON (30 | KAPTON (30 | KAPTON (30 | KAPTON (30 | KAPTON (30 |
| Laminate | | μm)/8146-1 | μm)/8146-1 | μm)/8146-1 | μm)/8146-1 | μm)/8146-1 | μm)/8146-1 |
| | | (manufactured | (manufactured | (manufactured | (manufactured | (manufactured | (manufactured |
| | | by 3M | by 3M | by 3M | by 3M | by 3M | by 3M |
| | | Company, 25 | Company, 25 | Company, 25 | Company, 25 | Company, 25 | Company, 25 |
| | | μm)/KAPTON | μm)/KAPTON | μm)/KAPTON | μm)/KAPTON | μm)/KAPTON | μm)/KAPTON |
| | | (125 μm) | (125 μm) | (125 μm) | (125 μm) | (125 μm) | (125 μm) |
| Evaluation | Breakage | 3 | 2 | 3 | 3 | 3 | 3 |
| | Peeling (Protective Film, | 4 | 4 | 3 | 2 | 4 | 3 |
| | Antireflection Film) | | | | | | |
| | Disconnection (Conductive | 3 | 3 | 4 | 4 | 4 | 4 |
| | Portion in Touch Sensor Film) | | | | | | |

TABLE 2

| | | | | | Comparative | Comparative | Comparative |
|---|---|---|---|---|---|---|---|
| | | Example 13 | Example 14 | Example 15 | Example 1 | Example 2 | Example 3 |
| Protective | Kind | PET | PET | PI | PET | PI | PET |
| Film | Thickness (μm) | 40 | 40 | 50 | 40 | 40 | 40 |
| Adhesive | Kind | 8146-2 | MO-3015C | MO-3015C | MO-3015C | MO-3015C | MO-3015C |
| Film | | (Manufactured | (manufactured | (manufactured | (manufactured | (manufactured | (manufactured |
| (Top) | | by 3M) | by Lintec | by Lintec | by Lintec | by Lintec | by Lintec |
| | | | Corporation) | Corporation) | Corporation) | Corporation) | Corporation) |
| | Thickness (μm) | 50 | 25 | 25 | 25 | 25 | 25 |
| | Adhesive Strength (N/mm) | 0.28 | 0.38 | 0.65 | 0.38 | 0.65 | 0.38 |
| | between Protective Film | | | | | | |
| | and Adhesive Film (Top) | | | | | | |
| | Adhesive Strength (N/mm) | 0.28 | 0.28 | 0.28 | 0.28 | 0.28 | 0.28 |
| | between Adhesive Film (Top) | | | | | | |
| | and Antireflection Film | | | | | | |
| Anti- | Kind | A | A | A | A | A | A |
| reflection | Thickness (μm) | 40 | 40 | 40 | 40 | 40 | 40 |
| Film | | | | | | | |
| Adhesive | Kind | MO-3015G | MO-3015G | MO-3015G | MO-3015C | MO-3015C | 8146-1 |
| Film | | (manufactured | (manufactured | (manufactured | (manufactured | (manufactured | (Manufactured |
| (Middle) | | by Lintec | by Lintec | by Lintec | by Lintec | by Lintec | by 3M) |
| | | Corporation) | Corporation) | Corporation) | Corporation) | Corporation) | |
| | Thickness (μm) | 50 | 50 | 50 | 25 | 25 | 25 |
| | Adhesive Strength (N/mm) | 0.66 | 0.66 | 0.66 | 0.39 | 0.39 | 0.23 |
| | between Antireflection Film | | | | | | |
| | and Adhesive Film (Middle) | | | | | | |
| | Adhesive Strength (N/mm) | 0.55 | 0.55 | 0.55 | 0.42 | 0.42 | 0.28 |
| | between Adhesive Film (Middle) | | | | | | |
| | and Conductive Film for Touch | | | | | | |
| | Sensor | | | | | | |
| Conductive | Kind | A | A | A | A | A | A |
| Film for | | (Ag Mesh) | (Ag Mesh) | (Ag Mesh) | (Ag Mesh) | (Ag Mesh) | (Ag Mesh) |
| Touch | | | | | | | |
| Sensor | | | | | | | |
| Adhesive | Kind | 8146-2 | 8146-2 | 8146-2 | 8146-2 | 8146-2 | 8146-2 |
| Film | | (Manufactured | (Manufactured | (Manufactured | (Manufactured | (Manufactured | (Manufactured |
| (Bottom) | | by 3M) | by 3M) | by 3M) | by 3M) | by 3M) | by 3M) |
| | Thickness (μm) | 50 | 50 | 50 | 50 | 50 | 50 |
| | Adhesive Strength (N/mm) | 0.31 | 0.31 | 0.31 | 0.31 | 0.31 | 0.31 |
| | between Conductive Film for | | | | | | |
| | Touch Sensor and | | | | | | |
| | Adhesive Film (Bottom) | | | | | | |
| | Adhesive Strength (N/mm) | 0.48 | 0.48 | 0.48 | 0.48 | 0.48 | 0.48 |
| | between Adhesive Film (Bottom) | | | | | | |
| | and Display Laminate | | | | | | |
| Display | Kind | KAPTON (30 | KAPTON (30 | KAPTON (30 | KAPTON (30 | KAPTON (30 | KAPTON (30 |
| Laminate | | μm)/8146-1 | μm)/8146-1 | μm)/8146-1 | μm)/8146-1 | μm)/8146-1 | μm)/8146-1 |
| | | (manufactured | (manufactured | (manufactured | (manufactured | (manufactured | (manufactured |
| | | by 3M | by 3M | by 3M | by 3M | by 3M | by 3M |
| | | Company, 25 | Company, 25 | Company, 25 | Company, 25 | Company, 25 | Company, 25 |
| | | μm)/KAPTON | μm)/KAPTON | μm)/KAPTON | μm)/KAPTON | μm)/KAPTON | μm)/KAPTON |
| | | (125 μm) | (125 μm) | (125 μm) | (125 μm) | (125 μm) | (125 μm) |
| Evaluation | Breakage | 2 | 2 | 2 | 1 | 1 | 1 |
| | Peeling (Protective Film, | 2 | 2 | 2 | 1 | 1 | 1 |
| | Antireflection Film) | | | | | | |
| | Disconnection (Conductive | 2 | 2 | 2 | 1 | 1 | 1 |
| | Portion in Touch Sensor Film) | | | | | | |

| | | Comparative | Comparative | Comparative | Comparative | Comparative |
|---|---|---|---|---|---|---|
| | | Example 4 | Example 5 | Example 6 | Example 7 | Example 8 |
| Protective | Kind | PET | PET | PET | PET | PET |
| Film | Thickness (μm) | 40 | 40 | 40 | 40 | 40 |
| Adhesive | Kind | 8146-1 | 8146-2 | MO-3015C | MO-3015C | MO-3015C |
| Film | | (Manufactured | (Manufactured | (manufactured | (manufactured | (manufactured |
| (Top) | | by 3M) | by 3M) | by Lintec | by Lintec | by Lintec |
| | | | | Corporation) | Corporation) | Corporation) |
| | Thickness (μm) | 25 | 50 | 25 | 25 | 25 |
| | Adhesive Strength (N/mm) | 0.23 | 0.28 | 0.38 | 0.38 | 0.38 |
| | between Protective Film | | | | | |
| | and Adhesive Film (Top) | | | | | |
| | Adhesive Strength (N/mm) | 0.24 | 0.28 | 0.28 | 0.28 | 0.28 |
| | between Adhesive Film (Top) | | | | | |
| | and Antireflection Film | | | | | |
| Anti- | Kind | A | A | A | A | A |
| reflection | Thickness (μm) | 40 | 40 | 40 | 40 | 40 |
| Film | | | | | | |
| Adhesive | Kind | 8146-2 | 8146-2 | MO-3015C | MO-3015C | MO-3015C |
| Film | | (Manufactured | (Manufactured by | (manufactured | (manufactured | (manufactured |
| (Middle) | | by 3M) | 3M) | by Lintec | by Lintec | by Lintec |
| | | | | Corporation) | Corporation) | Corporation) |
| | Thickness (μm) | 25 | 50 | 25 | 25 | 25 |
| | Adhesive Strength (N/mm) | 0.23 | 0.27 | 0.39 | 0.39 | 0.39 |
| | between Antireflection Film | | | | | |
| | and Adhesive Film (Middle) | | | | | |
| | Adhesive Strength (N/mm) | 0.28 | 0.31 | 0.47 | 0.41 | 0.45 |
| | between Adhesive Film (Middle) | | | | | |
| | and Conductive Film for Touch | | | | | |
| | Sensor | | | | | |
| Conductive | Kind | A | A | B | C | D |
| Film for | | (Ag Mesh) | (Ag Mesh) | (ITO Film) | (Cu Mesh) | (Ag Nanowire) |
| Touch | | | | | | |
| Sensor | | | | | | |
| Adhesive | Kind | 8146-2 | 8146-2 | 8146-2 | 8146-2 | 8146-2 |
| Film | | (Manufactured | (Manufactured | (Manufactured | (Manufactured | (Manufactured |
| (Bottom) | | by 3M) | by 3M) | by 3M) | by 3M) | by 3M) |
| | Thickness (μm) | 50 | 50 | 50 | 50 | 50 |
| | Adhesive Strength (N/mm) | 0.31 | 0.31 | 0.31 | 0.31 | 0.31 |
| | between Conductive Film for | | | | | |
| | Touch Sensor and | | | | | |
| | Adhesive Film (Bottom) | | | | | |
| | Adhesive Strength (N/mm) | 0.48 | 0.48 | 0.48 | 0.48 | 0.48 |
| | between Adhesive Film (Bottom) | | | | | |
| | and Display Laminate | | | | | |
| Display | Kind | KAPTON (30 | KAPTON (30 | KAPTON (30 | KAPTON (30 | KAPTON (30 |
| Laminate | | μm)/8146-1 | μm)/8146-1 | μm)/8146-1 | μm)/8146-1 | μm)/8146-1 |
| | | (manufactured | (manufactured | (manufactured | (manufactured | (manufactured |
| | | by 3M | by 3M | by 3M | by 3M | by 3M |
| | | Company, 25 | Company, 25 | Company, 25 | Company, 25 | Company, 25 |
| | | μm)/KAPTON | μm)/KAPTON | μm)/KAPTON | μm)/KAPTON | μm)/KAPTON |
| | | (125 μm) | (125 μm) | (125 μm) | (125 μm) | (125 μm) |
| Evaluation | Breakage | 1 | 1 | 1 | 1 | 1 |
| | Peeling (Protective Film, | 0 | 1 | 1 | 1 | 1 |
| | Antireflection Film) | | | | | |
| | Disconnection (Conductive | 0 | 1 | 1 | 1 | 1 |
| | Portion in Touch Sensor Film) | | | | | |

It was found from the results shown in Table 1 that, in a case where at least one adhesive film included as a member in the laminate for a touch panel has a 180 degree peel strength of 0.5 N/mm or higher with respect to an adjacent member and has a thickness of 30 or more, peeling between members in a bent portion can be suppressed.

In addition, it was found from a comparison between Examples 9, 10, 13, and 14 that, in the laminate for a touch panel, in a case where the adhesive film having the largest curvature (closest to the surface positioned on the inside) during the folding of the flexible device has a 180 degree peel strength of 0.5 N/mm or higher with respect to an adjacent member and has a thickness of 30 μm or more, breakage and disconnection can be further suppressed.

In addition, it was found from a comparison between Examples 1, 9, and 10 that, in a case where not only the adhesive film closest to the surface positioned on the inside during the folding of the flexible device but also the adhesive film positioned outside the surface have a 180 degree peel strength of 0.5 N/mm or higher with respect to an adjacent member and have a thickness of 30 μm or more (preferably, in a case where all the adhesive films in the laminate for a touch panel have a 180 degree peel strength of 0.5 N/mm or higher with respect to an adjacent member and have a thickness of 30 μm or more), peeling between members in a bent portion can be further suppressed.

It was found from a comparison between Examples 1, 4, 5, and 6 that, in a case where the conductive portion of the member (corresponding to the conductive film for a touch sensor) including the conductive portion in the laminate for a touch panel is the mesh pattern formed of thin silver wires, disconnection can be further suppressed.

It was found from a comparison between Examples 1, 7, and 8 that: in a case where the thickness of the adhesive film (Top) in the laminate for a touch panel is 145 μm or less, breakage is not likely to occur in the flexible device; and in a case where the thickness of the adhesive film (Top) is 95 μm or less, breakage is not likely to occur in the flexible device and disconnection of the conductive portion can be further suppressed.

It was found from a comparison between Examples 1, 12, and 13 that, in a case where the thickness of the adhesive film (Middle) is 95 μm or less, peeling can be further suppressed,

On the other hand, in Comparative Examples, all the adhesive films included as the members did not satisfy the following conditions: a 180 degree peel strength of 0.5 N/mm or higher with respect to an adjacent member; and a thickness of 30 μm or more. Therefore, peeling, breakage, and disconnected between members in a bent portion occurred.

### EXPLANATION OF REFERENCES

10: laminate for touch panel
12: conductive film for touch sensor
16: antireflection film
20: protective film
14, 18: adhesive film
L1: surface positioned on inside during curving
La1, La1, Lb1, Lb2: interface
L2: surface positioned on outside during curving
22: substrate
23: thin metal wire
36: opening
24: first detecting electrode
26: first lead-out wiring
28: second detecting electrode
30: second lead-out wiring
50: organic EL display device
52: light emitting portion
W: one side length of opening 36

What is claimed is:

1. A laminate for a touch panel that is bendable, comprising a plurality of members,
wherein at least one of the members is a member including a conductive portion,
at least one of the members is an adhesive film, and
the adhesive film has a 180 degree peel strength of 0.5 N/mm or higher with respect to an adjacent member and has a thickness of 30 μm or more.

2. The laminate for a touch panel according to claim 1,
wherein the 180 degree peel strength of the adhesive film with respect to the adjacent member is 0.6 N/mm or higher.

3. The laminate for a touch panel according to claim 1,
wherein the thickness of the adhesive film is 50 μm or more.

4. The laminate for a touch panel according to claim 2,
wherein the thickness of the adhesive film is 50 μm or more.

5. The laminate for a touch panel according to claim 1,
wherein at least two of the members are adhesive films, and
the adhesive film with the largest curvature among the adhesive films in a case where the laminate for a touch panel is bent has a 180 degree peel strength of 0.5 N/mm or higher with respect to an adjacent member and has a thickness of 30 μm or more.

6. The laminate for a touch panel according to claim 2,
wherein at least two of the members are adhesive films, and
the adhesive film with the largest curvature among the adhesive films in a case where the laminate for a touch panel is bent has a 180 degree peel strength of 0.5 N/mm or higher with respect to an adjacent member and has a thickness of 30 μm or more.

7. The laminate for a touch panel according to claim 3,
wherein at least two of the members are adhesive films, and
the adhesive film with the largest curvature among the adhesive films in a case where the laminate for a touch panel is bent has a 180 degree peel strength of 0.5 N/mm or higher with respect to an adjacent member and has a thickness of 30 urn or more.

8. The laminate for a touch panel according to claim 4,
wherein at least two of the members are adhesive films, and
the adhesive film with the largest curvature among the adhesive films in a case where the laminate for a touch panel is bent has a 180 degree peel strength of 0.5 N/mm or higher with respect to an adjacent member and has a thickness of 30 μm or more.

9. The laminate for a touch panel according to claim 1,
wherein the member including the conductive portion is a conductive film including a substrate and a conductive portion formed of a thin metal wire that is disposed on at least one surface of the substrate.

10. The laminate for a touch panel according to claim 2,
wherein the member including the conductive portion is a conductive film including a substrate and a conductive portion formed of a thin metal wire that is disposed on at least one surface of the substrate.

11. The laminate for a touch panel according to claim 3,
wherein the member including the conductive portion is a conductive film including a substrate and a conductive portion formed of a thin metal wire that is disposed on at least one surface of the substrate.

12. The laminate for a touch panel according to claim 4,
wherein the member including the conductive portion is a conductive film including a substrate and a conductive portion formed of a thin metal wire that is disposed on at least one surface of the substrate.

13. The laminate for a touch panel according to claim 5,
wherein the member including the conductive portion is a conductive film including a substrate and a conductive portion formed of a thin metal wire that is disposed on at least one surface of the substrate.

14. The laminate for a touch panel according to claim 9,
wherein the conductive portion is disposed on opposite surfaces of the substrate.

15. The laminate for a touch panel according to claim 9,
wherein the thin metal wire contains silver.

16. The laminate for a touch panel according to claim 9,
wherein the thin metal wire contains a binder.

17. An organic electroluminescence display device comprising:
the laminate for a touch panel according to claim 1; and
a light emitting portion including a light emitting layer and electrodes between which the light emitting layer is interposed.

18. A flexible device comprising:
the laminate for a touch panel according to claim 1.
